(19) United States
(12) Patent Application Publication
(10) Pub. No.: US 2013/0004760 A1
(43) Pub. Date: Jan. 3, 2013

(54) BIODEGRADABLE MOISTURE BARRIER FILM

(76) Inventor: Salvatore Pellingra, Newport, KY (US)

(21) Appl. No.: 13/538,342

(22) Filed: Jun. 29, 2012

Related U.S. Application Data
(60) Provisional application No. 61/503,710, filed on Jul. 1, 2011.

(51) Int. Cl. C08L 67/04; C23C 4/00; C23C 16/00; C08K 5/1545; B32B 37/24

(52) U.S. Cl. 428/220; 525/190; 524/47; 428/483; 428/339; 156/244.11; 427/255.6; 427/407.1; 427/446; 427/569

(57) ABSTRACT

Provided are biodegradable polylactic acid based film compositions. In one form, the film composition provided includes from 90 to 99 wt. % of one or more polylactic acid resins and from 1 to 10 wt. % of one or more polyterpene resin additives based on the total film structure. The film exhibits a lower water vapor transmission rate. Also provided are methods of making and using such film compositions.

### CROSS-REFERENCE TO RELATED APPLICATIONS

This is a Non-Provisional Application that claims priority to U.S. Provisional Application No. 61/503,710 filed on Jul. 1, 2011 and herein incorporated by reference herein in its entirety.

### FIELD

The present disclosure relates to the field of plastic films. It more particularly relates to biodegradable plastic packaging films including a combination of polylactic acid resin and polyterpenes to enhance moisture barrier properties.

### BACKGROUND

Resins such as polyethylene, polypropylene, polyethylene terephthalate, polyvinyl chloride and polyvinylidene chloride have been widely used for producing flexible packaging films. However, these resins are not biodegradable, and when discarded, they have negative influences on the environment. Of such resin films, those containing chlorine such as soft polyvinyl chloride and polyvinylidene chloride may release dioxins when incinerated.

In that situation, it is necessary to develop resins not having any negative influences on the environment, and biodegradable resins have been developed for such applications. Polylactic acid resins have been used to produce plastic films that are both compostable and biodegradable. A problem encountered with the use of such resins in packaging films is that the moisture barrier properties are compromised relative to packaging films of similar thickness, which are produced from non-compostable and non-biodegradable resins, such as polypropylene, polyethylene, polyester, polyvinyl chloride and polyvinylidene chloride. Moisture barrier properties are particularly important in food packaging applications as they correlate with the shelf life of food items packaged in such films.

U.S. Patent Publication No. 2002/0160201, herein incorporated by reference in its entirety, discloses a biodegradable oriented film of a plasticizer-containing biodegradable resin, of which the both surfaces are coated with at least one thin layer and of which the loop stiffness change after heat treatment at 130° C. for 30 minutes is at most 20%. The thin layer is made of at least one resin selected from polyester resins, acrylic resins, polyurethane resins, vinyl resins, epoxy resins, and amide resins. Plasticizers disclosed include ether-ester derivatives, glycerin derivatives, phthalic acid derivatives, glycolic acid derivatives, citric acid derivatives, adipic acid derivatives, and epoxy plasticizers. Preferred plasticizers are biodegradable ones such as triacetin, butyl esters of epoxidated linseed oil fatty acids, tributyl acetylcitrate, epoxidated soybean oil, and polyesters adipic acid with 1,3-butylene glycolic acid. The moisture barrier properties of the biodegradable oriented films are not disclosed.

A need exists for biodegradable packaging films with improved moisture barrier properties that maintain excellent biodegradability, recyclability and compostability.

### SUMMARY

According to the present disclosure, an advantageous biodegradable polylactic acid based film composition comprises from 90 to 99 wt. % of one or more polylactic acid resins and from 1 to 10 wt. % of one or more polyterpene resin additives based on the total film structure, wherein the film composition exhibits a water vapor transmission rate of less than or equal to 35 g/100 in²/day/mil.

A further aspect of the present disclosure relates to an advantageous method of making biodegradable polylactic acid based film composition comprising the steps of: providing a composition including 90 to 99 wt. % of one or more polylactic acid resins and from 1 to 10 wt. % of one or more polyterpene resin additives, and extruding the composition to form a mono-layer film, wherein the film exhibits a water vapor transmission rate of less than or equal to 35 g/100 in²/day/mil.

Another aspect of the present disclosure relates to an advantageous method of using a biodegradable polylactic acid based film composition comprising the steps of: providing a film composition including 90 to 99 wt. % of one or more polylactic acid resins and from 1 to 10 wt. % of one or more polyterpene resin additives, wherein the film composition exhibits a water vapor transmission rate of less than or equal to 35 g/100 in²/day/mil, and utilizing the film composition in frozen food packaging, snack food packaging, beverage packaging, labeling applications, pet food packaging applications for achieving recyclability, compostability and biodegradability following use.

These and other features and attributes of the disclosed biodegradable films compositions and methods of making of the present disclosure and their advantageous applications and/or uses will be apparent from the detailed description which follows.

### DETAILED DESCRIPTION

All numerical values within the detailed description and the claims herein are modified by “about” or “approximately” the indicated value, and take into account experimental error and variations that would be expected by a person having ordinary skill in the art. As used herein, the term “film” is use in the generic to include plastic web, regardless of whether it is a film or sheet. Also as used herein, the terms “biodegradable” and “compostable” when referring to films mean that they are certified as biodegradable and compostable in the United States and Europe, meeting BPI (Biodegradable Product Institute) standards for compostability (ASTM 6400D99 and ASTM6868) and European Bioplastics Standards (EN13432).

It is recognized that most biodegradable and compostable films, and in particular, those based on corn or starch, have poor resistance to moisture. There have been proposed numerous methods to improve the moisture barrier of such films, but these methods would typically take away from the natural or renewable features of the core ingredients and therefore compromise biodegradability and compostability. The Applicants have discovered that naturally occurring and renewable polyterpene based materials can be incorporated into biodegradable film structures to improve the moisture barrier properties of such films without compromising the biodegradability and compostability.

The present disclosure provides novel compositions for plastic packaging films that are not only biodegradable and compostable, but also exhibit outstanding moisture barrier properties. The present disclosure also provides for methods of making and using such novel biodegradable plastic films. The compositions of current disclosure are distinguishable over the prior art in providing a combination of a polylactic acid resin or a polylactic acid blend resin with one or more naturally occurring polyterpene resin modifiers to maintain biodegradability and compostability while improving moisture barrier properties relative to biodegradable films not including such polyterpene resin modifiers. The biodegradable film compositions of the present disclosure offers significant advantages relative to prior art biodegradable compositions in having improved moisture barrier properties. The advantageous properties and/or characteristics of the disclosed biodegradable films are based, at least in part, on the synergistic effect imparted by the combination of polylactic acid resins and blend resins with low levels of naturally ocurring polyterpene resin modifiers included therein, which include, inter alia, improved moisture barrier properties and stiffness. The improved moisture barrier properties and stiffness properties provided by the combination of polylactic acid resins and blend resins with low levels of naturally ocurring polyterpene resin modifiers are surprising and unexpected.

U.S. Pat. No. 5,500,282, the entire disclosure of which is hereby incorporated herein by reference, discloses the use of polyterpenes to improve the moisture barrier properties of high crystallinity polypropylene containing films. Such films however suffer in being neither biodegradable nor compostable.

### Exemplary Biodegradable Film Structures

In one non-limiting exemplary embodiment of the present disclosure, the biodegradable film composition includes one or more polylactic acid based resins with from 1 to 10 wt. % of one or more polyterpene resins. The resulting films have moisture barrier properties that are 3 to 40% lower than control films not including one or more naturally occurring polyterpene resins, while maintaining outstanding biodegradability, recyclability and compostability.

The thickness of the biodegradable film is not particularly limited; however, the thickness may range from 0.5 mil to 20 mil, or 1 mil to 15 mil, or 2 mil to 10 mil, or mil to 7 mil. Generally the application of the film dictates the thickness required depending upon the mechanical properties, stiffness and barrier properties desired.

In an alternative embodiment of the present disclosure, the biodegradable film composition includes a core layer of one or more polylactic acid based resins with from 1 to 10 wt. % of one or more polyterpene resins and one or more skin layers to provide sealability or other functional properties to the film. The one or more skin layers may be made from low stereo regular polyolefin polymers and include, for example, ethylene-propylene (EP) random copolymers and ethylene-propylene-butene-1 (EPB) terpolymers, low density polyethylene, linear low density polyethylene, propylene-butene-1 copolymer, ethylene vinyl alcohol copolymer, amorphous polyester, and ionomer. Preferred copolymers are ethylene-propylene random copolymers having 1 to 15 wt. % ethylene, or 2 to 12 wt. % ethylene, or 4 to 10 wt. % ethylene, or 5 to 9 wt. % ethylene. Preferred terpolymers are ethylene-propylene-butene-1 terpolymers having 1-5 wt. % ethylene and 1-15 wt. % butene-1.

The thickness of the one or more skin layers should be generally minimized to minimize the detrimental impact on the recyclability, compostability and biodegradability of the overall film. In particular, the skin layer thickness may be less than or equal to 20 gauge units, or less than or equal to 15 gauge units, or less than or equal to 10 gauge units, or less than or equal to 5 gauge units, or less than or equal to 3 gauge units, or less than or equal to 1 gauge units.

The one or more skin layers may be surface treated to enhance surface energy and wettability by providing oxygen containing species and groups on the surface. Non-limiting exemplary surface treatment processes include corona discharge treatment, flame treatment, plasma treatment, and combinations thereof.

In this embodiment including one or more skin layers, one or more tie layers may be utilized to achieve adequate adhesion between the PLA based core layer and the one or more skin layers. Maleic anhydride modified polymers are particularly advantageous for tie layers between non-polar skin layers and a polar PLA based core layer. More particularly, a maleic anhydride modified polypropylene or polyethylene may be used as a tie layer in a multilayer film structure. Like the one or more skin layers, it is advantageous to minimize the thickness of the one or more skin layers to minimize the detrimental impact on the recyclability, compostability and biodegradability of the overall film. In particular, the tie layer thickness may be less than or equal to 20 gauge units, or less than or equal to 15 gauge units, or less than or equal to 10 gauge units, or less than or equal to 5 gauge units, or less than or equal to 3 gauge units, or less than or equal to 1 gauge units.

In yet another exemplary embodiment of the present disclosure, the biodegradable film composition includes a core layer of one or more polylactic acid based resins with from 1 to 10 wt. % of one or more polyterpene resins, and one or more coating layers on one or both sides of the polylactic acid containing core layer to provide further enhancement to the properties of the film. For example, moisture barrier capability can be further enhanced by coating the biodegradable film disclosed herein with one or more polyvinylidene chloride (PVDC) coating layers as taught in U.S. Pat. Nos. 5,057,177; 5,019,447; and 4,961,992, herein incorporated by reference in their entirety. In addition, oxygen barrier can be enhanced by coating the biodegradable film with one or more PVOH coating layers, as described in U.S. Pat. No. 5,230,963, herein incorporated by reference in its entirety. In addition, sealability and flavor/aroma barrier protection may be improved by coating the biodegradable films with one or more acrylic coating layers, as described in U.S. Pat. Nos. 4,058,649 and 4,058,645, herein incorporated by reference in their entirety. A low temperature sealable coating (LTSC) as known in the art may be applied in order to provide machinability and high speed horizontal form and fill applications, as described in U.S. Pat. Nos. 5,419,960 and 6,013,353, herein incorporated by reference in their entirety. Moreover, any combination of PVDC, PVOH, acrylic and LTSC coatings may be utilized to provide for a combination of biodegradable film attributes described above. Like the one or more skin and tie layers described above, it is advantageous to minimize the thickness of the one or more coating layers to minimize the detrimental impact on the recyclability, compostability and biodegradability of the overall film. In particular, the coating layer thickness may be less than or equal to 10 gauge units, or less than or equal to 5 gauge units, or less than or equal to 3 gauge units, or less than or equal to 1 gauge units, or less than or equal to 0.5 gauge units, or less than or equal to 0.2 gauge units.

In still yet another exemplary embodiment of the present disclosure, the biodegradable film composition includes a core layer of one or more polylactic acid based resins with from 1 to 10 wt. % of one or more polyterpene resins, and one or more vacuum deposited aluminum layers (metalized layers) on one or both sides of the polylactic acid containing core layer to provide further enhancement to the light barrier, oxygen barrier and moisture properties of the film as described in U.S. Pat. Nos. 4,345,005, 5,153,074, 5,194,318, herein incorporated by reference in their entirety. The optical density of the metalized film, which is a measure of the metal layer coating thickness, may range from 0.5 to 4.0, or 1.0 to 3.0, or 1.5 to 2.5 with again lower thicknesses preferred for sustainability of biodegradability, recyclability, and compostability.

The core layer and/or the one or more skin layers of the biodegradable film compositions disclosed herein may also include one or more agro-derived bioresins. Non-limiting exemplary forms of agro-derived bioresins include green polyethylene, green polypropylene and green polyester. These agro-derived bioresins described in further detail below may be included in the core layer of the biodegradable film compositions at from 1 to 20 wt. %, or 3 to 15 wt. %, or 5 to 10 wt. % without significantly sacrificing the biodegradability, recyclability, and compostability of the biodegradable film compositions disclosed herein. The one or more skin layers of the biodegradable film compositions disclosed herein may also be formed from one or more agro-derived bioresins described below. These agro-derived bioresins may be included in the one or more skin layers of the biodegradable film compositions at from 1 to 100 wt. %, or 5 to 95 wt. %, or 10 to 90 wt. %, or 20 to 80 wt. %, or 30 to 70 wt. %, or 40 to 60 wt. % without significantly sacrificing the biodegradability, recyclability, and compostability of the biodegradable film compositions disclosed herein.

One type of green polyethylene is produced by Braskem in Brazil. The process utilizes sugarcane based ethanol to produce polyethylene. However, other hydrolyzed starches and advantageously hydrolyzed cellulose or hemicelluloses may be fermented to also produce agro-derived ethanol. Because sugarcane is a relatively inexpensive and a highly productive crop, it may be used to produce ethanol that is more cost effective and higher yielding than U.S. corn based ethanol. Green polyethylene resins may also be considered renewable and maintain the same properties, including recyclability, as petroleum or natural gas based polyethylene resins. However, much like petroleum or natural gas based polyethylene resins, green polyethylene resins are not biodegradable or compostable. Green polypropylene resins utilize similar production technologies as green polyethylene resins and are also under development by Braskem.

PET resin is made from PTA (purified terephthalic acid) or DMT (dimethyl terephthalate) and MEG (monoethylene glycol). Green PET resin is made from PTA and green MEG. Green MEG is made from agro-derived sources, including, but not limited to, sugarcane, whereas conventional MEG is made using crude oil sources. Green MEG may be included in the PET product at 30 wt. %. Green PET resins perform equivalently to petrochemical based PET resins, and may also be recycled, but should not be mistaken for compostable or biodegradable. Green PTA may be produced from other plant products such as switch grass, pine bark and corn husks to produce plant-based PTA or other PTA replacements to produce 100% renewable green PET resins. Green PET is currently produced in India by Uflex.

### Polylactic Acid Resin and Polylactic Acid Blend Resin

As used herein, the terms “polylactic acid” and “polylactide” are used synonymously throughout this disclosure to describe homopolymers or copolymers having an ester linkage between monomer units and can be represented by the general formula: [—OCH(R)C(O)—]ₙ where R═CH₃. Polylactic acid may be fabricated by polymerizing lactic acid, which is mostly produced from by carbohydrate fermentation of corn. Polylactic acid may be also produced by polymerization of lactide which obtained by condensation of two lactic acid molecules. Polylactic acid has a glass transition temperature of ranges from 50-80° C. while the melting temperature ranges from 130-180° C. Polylactic acid is known by those skilled in the art and fully disclosed in U.S. Pat. Nos. 5,698,322; 5,142,023; 5,760,144; 5,593,778; 5,807,973; and 5,010,145, the entire disclosure of each of which is hereby incorporated by reference. Examples of commercially available polylactic acid resins are sold under the trademark NatureWorks™ PLA Polymer in grades 4031-D, 4032-D, and 4041-D from Cargill Dow LLC, Minneapolis, Minn., U.S.A. In addition, PLA blend resins, composed of PLA with native plant starches (corn, wheat, tapioca and potato) are also suitable for the improved moisture barrier PLA films disclosed herein. PLA blend resins are sold under the trademark Compostable® by Cereplast, Inc. A particularly preferred PLA blend resin is Compostable® 3000 for blown film applications.

The polylactic acid resin means a polymer in which L-form lactic acid and/or D-form lactic acid are the main constituting unit (monomer component). The polylactic acid resin may contain other copolymer components than lactic acid as a constituting unit of the polylactic acid resin, such other constituting units include glycol compounds such as ethylene glycol, propylene glycol, butane diol, heptane diol, hexane diol, octane diol, nonane diol, decane diol, 1,4-cyclohexane dimethanol, neopentyl glycol, glycerin, pentaerythritol, bisphenol A, polyethylene glycol, polypropylene glycol and polytetramethylene glycol; dicarboxylic acids such as oxalic acid, adipic acid, sebacic acid, azelaic acid, dodecane dioic acid, malonic acid, glutaric acid, cyclohexane dicarboxylic acid, terephthalic acid, isophthalic acid, phthalic acid, naphthalene dicarboxylic acid, bis(p-carboxyphenyl) methane, anthracene dicarboxylic acid, 4,4′-diphenyl ether dicarboxylic acid, 5-sodium sulfoisophthalate and 5-tetrabutyl phosphonium isophthalic acid; hydroxycarboxylic acids such as glycolic acid, hydroxypropionic acid, hydroxybutyric acid, hydroxyvaleric acid, hydroxycaproic acid and hydroxybenzoic acid: and lactones such as caprolactone, valerolactone, propiolactone, undecalactone, 1,5-oxepane-2-on.

The polylactic acid resin refers to a resin in which the lactic acid units account for 50 mol. % or more and 100 mol % or less relative to the total constituting units in the polymer which is taken as 100 mol %, but in view of the extrusion characteristics, it is preferably 60 mol % or more and 100 mol % or less and still more preferably 80 mol % or more and 100 mol % or less.

For applications in which thermal resistance is required, it is preferable to use a polylactic acid resin whose optical purity of lactic acid unit is high, as the polylactic acid resin or the like which is the main component of the resin composition (A). That is, it is preferable that, in the total 100 mol % lactic acid units in the polylactic acid resin, L-form lactic acid units account for 80 mol % or more and 100 mol % or less or D-form lactic acid units account for 80 mol % or more and 100 mol % or less, and it is more preferable that L-form lactic acid units account for 90 mol % or more and 100 mol % or less or D-form lactic acid units account for 90 mol % or more and 100 mol % or less. It is still more preferable that L-form lactic acid units account for 95 mol % or more and 100 mol % or less or D-form lactic acid units account for 95 mol % or more and 100 mol % or less, and it is most preferable that L-form lactic acid units account for 98 mol % or more and 100 mol % or less or D-form lactic acid units account for 98 mol % or more and 100 mol % or less.

In addition, for applications in which thermal resistance is required, it is preferable to use polylactic acid stereocomplex as the polylactic acid resin or the like which is the main component of the resin composition (A). A method helpful for forming a polylactic acid stereocomplex is mixing, with a technique such as melt-kneading or solution mixing, a poly-L-lactic acid in which L-form lactic acid units account for 90 mol % or more and 100 mol % or less, preferably 95 mol % or more, and more preferably 98 mol % or more to form a more effective stereocomplex, of the total 100 mol % lactic acid units in the total polylactic acid resin, with a poly-D-lactic acid in which D-form lactic acid units account for 90 mol % or more and 100 mol % or less, preferably 95 mol % or more, and more preferably 98 mol % or more to form more effective stereocomplexes, of the total 100 mol % lactic acid units. Another method for forming a polylactic acid stereocomplex is to produce a block copolymer consisting of poly-L-lactic acid segments and poly-D-lactic acid segments. The use of a block copolymer consisting of poly-L-lactic acid segments and poly-D-lactic acid segments is preferable for easy formation of a polylactic acid stereocomplex. For this disclosure, a polylactic acid stereocomplex may be used alone or a polylactic acid stereocomplex may be used in combination with a poly-L-lactic acid or a poly-D-lactic acid. A poly-L-lactic acid and a poly-D-lactic acid refer to a resin in which 50 mol % or more of the total 100 mol % lactic acid units is accounted for by L-form lactic acid units or D-form lactic acid units, respectively.

For production of a polylactic acid resin, known polymerization methods can be used, such as direct polymerization from lactic acid and ring-opening polymerization via a lactide. The molecular weight and molecular weight distribution of the polylactic acid resin are not particularly limited as far as extrusion processing is substantially possible, but the weight average molecular weight is usually 10,000 to 500,000, preferably 40,000 to 300,000 and more preferably 80,000 to 250,000.

The melting point of the polylactic acid resin is, in view of thermal resistance, preferably 120° C. or more, and more preferably 150° C. or more. The upper limit is not particularly limited, but it is 190° C. in most cases. An amorphous polylactic acid resin which shows no melting point can also be used, but in view of mechanical properties and gas barrier property of the film, it is preferable to use a crystalline polylactic acid resin.

Additionally, as long as the physical properties of the resins are not impaired, the following various additives may be added to the resins: a hydrolysis resistant agent, a terminal blocking agent, a pigment, a fragrance, a dye, a delustering agent, a heat stabilizer, an antioxidant, a plasticizer, a lubricant, a release agent, a light resistant agent, an antiweathering agent, a flame retardant, an antibacterial agent, a surfactant, a surface modifier, an antistatic agent, a filler and the like.

### Polyterpene Resin and Moisture Barrier Improvement

As used herein, the term “tackifier” is generally an adhesive additive which serves to modify the rheological properties of the final adhesive. More specifically, a tackifier resin improves the tack of the adhesive composition. As used herein, the term “tack” refers to the “stickiness” of the adhesive or its resistance to removal or deformation from a substrate. Polyterpenes have typically been used in the packaging industry as tackifiers for adhesives and film compounding. Used primarily as a modifier, polyterpenes can improve adhesion of films within a multi-layer construction or enhance heat seal properties.

The Applicants have unexpectedly discovered that when one or more polyterpenes are blended with polylactic acid resin, and formed into a film, the moisture barrier properties of the film is significantly improved. The polylactic acid resin may be blended with less than or equal to 10 wt. %, preferably less than or equal to 7 wt. %, e.g., 3 to 6 wt. %, or even more preferably less than or equal to 5 wt. %, say, 1 to 3 wt. % of a polyterpene component. It has been found that the incorporation of terpene polymers at low levels in the polylactic acid resin provides a product film having significantly improved moisture barrier properties. Such films can be produced in accordance with the present disclosure having water vapor transmission rates (WVTR) less than or equal to 39, or 37, or 35, or 33, or 30, or 27, or 25, or 23, or even 20 g/100 in²/day/mil, as measured per ASTM F-372 at 100° F. and 90% relative humidity (RH). In contrast, the polylactic acid resin without the polyterpene component has a WVTR of greater than or equal to 39, or 41, or 43, or 45, or 47, or 50 g/100 in²/day/mil, as measured per ASTM F-372 at 100° F. and 90% relative humidity (RH). Hence, the Applicants have discovered that with the addition of low levels of polyterpene (less than or equal to 10 wt. %) the moisture barrier of terpene modified PLA film may be improved by at least 3%, or 5%, or 7%, or 10%, or 15%, or 20%, or 25%, or 30%, or 35%, or 40% compared to a control PLA film without any polyterpene component.

The polyterpene may be produced by polymerization and/or copolymerization of terpene hydrocarbons such as the monocyclic, and bicyclic monoterpenes and their mixtures, including allo-ocimene, carene, isomerized pinene, pinene, dipentene, terpinene, terinolene, limonene, turpentine, a terpene cut or fraction, and various other terpenes. The polymerization and/or copolymerization may be followed by hydrogenation under pressure. Preferred polyterpenes are those selected from the group consisting of polymerized d-limonene, polymerized beta-pinene, or a polymerized synthetic approximation of d-limonene and beta-pinene and mixtures thereof. The preferred polyterpenes have a molecular weight of from 800 to 15,000 Mn. Other examples of the polyterpene resin include the terpenes obtained from β-pinene, terpene phenol resin and the hydrogenated products of these resins. Particularly preferable among these is terpene phenol resin. The softening point of the polyterpene is preferably 40 to 200° C., more preferably 70 to 150° C. and particularly preferably 90 to 150° C. Specific examples of the polyterpene include “Mighty Ace”, “YS Polyster” (a terpene-phenol resin, softening point: 100 to 150° C., weight average molecular weight: 500 to 1050) and “Clearon” (a hydrogenated terpene resin, softening point: 80 to 130° C., weight average molecular weight: 600 to 700) (all of these three are manufactured by Yasuhara Chemical Co., Ltd.). Other examples of suitable polyterpenes are Piccolyte® C115, Piccotac® 1100 and Polypale® 100 available from Hercules-Aqualon. A particularly preferred polyterpene is Piccolyte® C115, which is a polymerized d-limonene polyterpene.

In addition, the biodegradability and compostablility of the PLA film is not compromised by the terpene additive, which is a naturally occurring compound used in the manufacture of polyterpenes.

### Other Film Additives

The biodegradable films disclosed herein may be further enhanced in terms of properties by incorporating film additives. Such additives are used in effective amounts, which vary depending upon the property required, and are, typically selected from the group consisting of: antiblock, slip additive, and antioxidant additive. These additives may be included in any of the film's layers. Useful antistatic additives which can be used in amounts ranging from 0.05 to 3 weight %, based upon the weight of the layer, include alkali metal sulfonates, polyether-modified polydiorganosiloxanes, polyalkylphenylsiloxanes and tertiary amines. Useful antiblock additives used in amounts ranging from 0.1 weight % to 3 weight % based upon the entire weight of the layer include inorganic particulates such as silicon dioxide, e.g. a particulate antiblock sold by W. R. Grace under the trademark “Sylobloc 44,” calcium carbonate, magnesium silicate, aluminum silicate, calcium phosphate, and the like, e.g., KAOPOLITE. Another useful particulate antiblock agent is referred to as a non-meltable crosslinked silicone resin powder sold under the trademark “TOSPEARL” made by Toshiba Silicone Co., Ltd. and is described in U.S. Pat. No. 4,769,418. Another useful antiblock additive is a spherical particle made from methyl methacrylate resin having an average diameter of 1 to 15 microns, such an additive may be sold under the trademark “EPOSTAR” and may be commercially available from Nippon Shokubai. Typical slip additives include higher aliphatic acid amides, higher aliphatic acid esters, waxes and metal soaps which can be used in amounts ranging from 0.1 to 2 weight percent based on the total weight of the layer. A specific example of a useful fatty amide slip additive may be erucamide. Useful antioxidants are generally used in amounts ranging from 0.1 weight % to 2 weight percent, based on the total weight of the layer, phenolic antioxidants. One useful antioxidant may be commercially available under the trademark “Irganox 1010”. Optionally, one or more of the film's layers may be compounded with a wax for lubricity. Amounts of wax range from 2 to 15 weight % based on the total weight of the layer. Any conventional wax useful in thermoplastic films may be contemplated.

### Method of Making

In one non-limiting exemplary embodiment of making the biodegradable film composition, the method includes providing one or more polylactic acid based resins with from 1 to 10 wt. % of one or more polyterpene resins and extruding the combination of the polylactic acid based resins and the one or more polyterpene resins to form a mono-layer film. The resulting films have moisture barrier properties that are 3 to 40% lower than control films not including one or more naturally occurring polyterpene resins, while maintaining outstanding biodegradability, recyclability and compostability.

The polyterpene may be compounded into the PLA resin at the loadings indicated above using conventional melt compounding process, which include, but are not limited to a single screw compounding extruder, a twin screw compounding extruder, and a banbury type mixer. For example, a masterbatch of PLA resin with polyterpene may be produced in a prior compounding step. The masterbatch may include from 10 to 60 wt. % of the polyterpene in the PLA resin, which can be subsequently let down during the film forming extruding step to polyterpene loadings in the film of from 1 to 10 wt. %.

Alternatively, the polyterpene resin may be directly metered into the PLA resin during the film forming process by in-line extrusion processing the two components. For example, the polyterpene may be fed to a single screw film forming extruder via a gravimetric type blender or a volumetric type blender position at a down stream feed port of the film extruder with the mixing of the PLA resin and the polyterpene resin occurring during the film processing extruder. Alternatively, the in the case where the polyterpene is in-line blended with the PLA resin during the film making step, the polyterpene may be fed to the film forming extruder at the hopper along with the PLA resin using a gravimetric or volumetric type blender for controlling the weight percentages of the two components.

It may be also advantageous that the film forming extruder screw have one or more mixing elements or sections for improving dispersion of the polyterpene into the PLA melt. This in-line blending method alleviates the need and the cost for a separate compounding step. The biodegradable films disclosed herein may be produced on conventional blown film and cast film equipment using melt extrusion processing. In addition, the cast or blown film may be optionally stretched in the machine direction, the transverse direction or both to further improve properties and WVTR. When the film is oriented in both directions (biaxial orientation), the orientation may be successive biaxial stretching (MD followed by TD, or TD followed by MD) or alternatively simultaneous biaxial stretching. As described above, it may be also advantageous to treat the surface(s) of the biodegradable films disclosed herein via corona, plasma, or flame treatment processes.

For embodiments including skin layers, and/or tie layers, coextrusion processing methods, such a coextrusion mixing blocks and/or multi-layer manifold dies, may be utilized to form multi-layer film structures. For embodiments including coating layers, coating processing methods, such as direct gravure, or indirect gravure methods, may be utilized to form coated film structures. For embodiments including metalized aluminum layers, vacuum metalizing processing methods, such as conventional vacuum deposition or electron beam deposition, may be utilized to form metallized film structures.

### Applications and Advantages

The terpene containing PLA films disclosed herein may be utilized in the following non-limiting types of applications and uses: frozen food packaging, snack food packaging, beverage packaging, labeling applications, and pet food packaging,

Generally, PLA films have poor moisture barrier properties, which limit their application in food packaging and other applications. The advantages of the disclosed PLA films comprising one or more polyterpenes, include, inter alia, improved moisture barrier properties, excellent mechanical properties (tensile strength, elongation to break, modulus/stiffness, etc.), excellent recyclability and excellent compostability. By enhancing the moisture barrier properties without negatively impacting the compostability of the terpene containing PLA film, the suitability of PLA films in more applications is made possible. Moreover, the compostability and recyclability of biodegradable PLA films is usually compromised because of the need to use PLA films with coextruded or coated layers made from traditional petrochemical resins, which are not degradable. The PLA films including polyterpene disclosed herein reduce the dependency of such non-biodegradable resins for moisture barrier properties.

### Test Methods

The determination of WVTR was determined by ASTM test method F-372 at 100° F. and 90% relative humidity (RH).

The following are examples of the present disclosure and are not to be construed as limiting.

### EXAMPLES

### Illustrative Example 1

Hercules-Aqualon Piccolyte® C115 (a polymerized d-limonene) polyterpene was compounded into a PLA blend resin (Compostable® 3000 by Cereplast, Inc.) for blown film extrusion applications. Mono-layer film samples were produced on a conventional mono-layer blown film line with 0, 3 and 6 wt. % of Piccolyte® C115 in the PLA resin. Films produced were measured for WVTR in units of g/100 in²/day at 100° F. and 90% relative humidity (RH). To account for film gauge, the WVTR of all samples were normalized to 1 mil thickness to allow a direct comparison of film samples with different polyterpene loading levels. The results are shown in Table 1 below.

TABLE 1
WVTR of PLA Films as a Function of Polyterpene Loading

| | | | | WVTR |
|---|---|---|---|---|
| | Wt. % | Gauge | | normalized |
| Sample | polyterpene | (mil) | WVTR | for 1 mil |
| F1 (inventive 1) | 3 | 3.5 | 9.69 | 33.9 |
| F1 (inventive 2) | 3 | 3.4 | 10.10 | 34.3 |
| F2 (inventive 3) | 6 | 1.9 | 13.50 | 25.7 |
| F2 (inventive 4) | 6 | 2.9 | 9.82 | 28.5 |
| C3000 | 0 | 3 | 13.10 | 39.3 |
| (comparative 1) | | | | |
| C3000 | 0 | 3.3 | 12.50 | 41.3 |
| (comparative 2) | | | | |

The results show that at low polyterpene loading (6 wt. % or less), the moisture barrier of the polyterpene modified PLA film was improved by 13 to 38% compared to the control film (C3000 with 0 wt. % polyterpene). Moreover, neither the compostability nor recyclability of the PLA film was compromised by the addition of the polyterpene, which is a naturally occurring compound derived from a renewable source.

### Alternative Embodiments

In a first aspect, a biodegradable polylactic acid based film composition is provided. The biodegradable polylactic acid based film composition includes from 90 to 99 wt. % of one or more polylactic acid resins and from 1 to 10 wt. % of one or more polyterpene resin additives based on the total film structure, wherein the film composition exhibits a water vapor transmission rate of less than or equal to 35 g/100 in²/day/mil.

In accordance with a second aspect, the film of the first aspect exhibits a water vapor transmission rate of less than or equal to 30 g/100 in²/day/mil.

In accordance with the second aspect the film exhibits a water vapor transmission rate of less than or equal to 25 g/100 in²/day/mil.

In accordance with the first aspect, the one or more polyterpene resin additives range from 3 to 6 wt. % based on the total film structure.

In accordance with a third aspect, the one or more polyterpene resin additives of the first aspect are chosen from a polymerized d-limonene, a polymerized beta-pinene, a polymerized synthetic approximation of d-limonene and beta-pinene, and combinations thereof.

In accordance with the third aspect, the one or more polyterpene resin additives comprises polymerized d-limonene.

In accordance with the first aspect, the film composition has a thickness ranging from 0.5 mil to 20 mil.

In accordance with a fourth aspect, the one or more polylactic acid resins of the first aspect includes a polylactic acid blend resin comprising polylactic acid with one or more native plant starches.

In accordance with the fourth aspect, the one or more native plant starches are chosen from corn, wheat, tapioca, potato and combinations thereof.

In accordance with a fifth aspect, the film composition of the first aspect further includes one or more skin layers on one or both sides of the polylactic acid containing layer, wherein the skin layers are chosen from ethylene-propylene random copolymer, ethylene-propylene-butene-1 terpolymer, high density polyethylene, medium density polyethylene, low density polyethylene, linear low density polyethylene, propylene-butene-1 copolymer, ethylene vinyl alcohol copolymer, amorphous polyester, ionomer and combinations thereof.

In accordance with the fifth aspect, the thickness of the more or more skin layers range from 1 to 20 gauge units.

In accordance with the fifth aspect, the film composition further includes one or more tie layers interposed between the one or more skin layers and the polylactic acid containing layer, wherein the tie layer is a maleic anhydride modified polyethylene or polypropylene. Further, the thickness of the more or more tie layers range from 1 to 20 gauge units.

In accordance with the fifth aspect, the one or more skin layers further include from 5 to 95 wt. % of one or more agro-derived bioresins chosen from green polyethylene, green polypropylene, green polyester, and combinations thereof.

In accordance with a sixth aspect, the film composition of the first aspect further includes one or more coating layers on one or both sides of the polylactic acid containing layer, wherein the coating layers are chosen from PVDC, PVOH, acrylic, LTSC and combinations thereof.

In accordance with the sixth aspect, the thickness of the more or more coating layers range from 0.2 to 10 gauge units.

In accordance with a seventh aspect, the film composition of the first aspect further includes one or more vacuum deposited aluminum layers on one or both sides of the polylactic acid containing layer.

In accordance with the seventh aspect, the optical density of the film composition is from 0.5 to 4.0.

In accordance with the first aspect, the film composition further includes from 1 to 20 wt. % of one or more agro-derived bioresins chosen from green polyethylene, green polypropylene, green polyester, and combinations thereof.

In accordance with an eighth aspect, a method of making a biodegradable polylactic acid based film composition is provided. The method includes: providing a composition including 90 to 99 wt. % of one or more polylactic acid resins and from 1 to 10 wt. % of one or more polyterpene resin additives, and extruding the composition to form a mono-layer film, wherein the film exhibits a water vapor transmission rate of less than or equal to 35 g/100 in²/day/mil.

In accordance with the eighth aspect, the one or more polyterpene resin additives are chosen from a polymerized d-limonene, a polymerized beta-pinene, a polymerized synthetic approximation of d-limonene and beta-pinene, and combinations thereof.

In accordance with the eighth aspect, the film composition has a thickness ranging from 0.5 mil to 20 mil.

In accordance with a ninth aspect, the one or more polylactic acid resins of the eighth aspect includes a polylactic acid blend resin comprising polylactic acid with one or more native plant starches.

In accordance with the ninth aspect, the one or more native plant starches are chosen from corn, wheat, tapioca, potato and combinations thereof.

In accordance with a tenth aspect, the method of the eighth aspect further includes coextruding one or more skin layers on one or both sides of the mono-layer film, wherein the skin layers are chosen from ethylene-propylene random copolymer, ethylene-propylene-butene-1 terpolymer, high density polyethylene, medium density polyethylene, low density polyethylene, linear low density polyethylene, propylene-butene-1 copolymer, ethylene vinyl alcohol copolymer, amorphous polyester, ionomer and combinations thereof.

In accordance with the tenth aspect, the method further includes coextruding one or more tie layers interposed between the one or more skin layers and the polylactic acid containing layer, wherein the tie layer is a maleic anhydride modified polyethylene or polypropylene.

In accordance with the tenth aspect, the one or more skin layers further include from 5 to 95 wt. % of one or more agro-derived bioresins chosen from green polyethylene, green polypropylene, green polyester, and combinations thereof.

In accordance with the eighth aspect, the method further includes coating one or more coating layers on one or both sides of the of the mono-layer film, wherein the coating layers are chosen from PVDC, PVOH, acrylic, LTSC and combinations thereof.

In accordance with the eighth aspect, the method further includes vacuum metallizing one or more aluminum layers on one or both sides of the mono-layer film, wherein the optical density of the film composition is from 0.5 to 4.0.

In accordance with the eighth aspect, the method further includes surface treating one or more surfaces of the mono-layer film by corona discharge treatment, flame treatment, plasma treatment, or combinations thereof.

In accordance with the eighth aspect, the method further includes machine direction orienting the mono-layer film.

In accordance with the eighth aspect, the method further includes transverse direction orienting the mono-layer film.

In accordance with the eighth aspect, the method further includes the combination of machine direction orienting and transverse direction orienting the mono-layer film.

In accordance with the eighth aspect, the method further includes from 1 to 20 wt. % of one or more agro-derived bioresins chosen from green polyethylene, green polypropylene, green polyester, and combinations thereof.

In accordance with an eleventh aspect, a method of using a biodegradable polylactic acid based film composition is provided. The method includes: providing a film composition including 90 to 99 wt. % of one or more polylactic acid resins and from 1 to 10 wt. % of one or more polyterpene resin additives, wherein the film composition exhibits a water vapor transmission rate of less than or equal to 35 g/100 in²/day/mil, and utilizing the film composition in frozen food packaging, snack food packaging, beverage packaging, labeling applications, pet food packaging applications for achieving recyclability, compostability and biodegradability following use.

Applicants have attempted to disclose all embodiments and applications of the disclosed subject matter that could be reasonably foreseen. However, there may be unforeseeable, insubstantial modifications that remain as equivalents. While the present invention has been described in conjunction with specific, exemplary embodiments thereof, it is evident that many alterations, modifications, and variations will be apparent to those skilled in the art in light of the foregoing description without departing from the spirit or scope of the present disclosure. Accordingly, the present disclosure is intended to embrace all such alterations, modifications, and variations of the above detailed description.

All patents, test procedures, and other documents cited herein, including priority documents, are fully incorporated by reference to the extent such disclosure is not inconsistent with this invention and for all jurisdictions in which such incorporation is permitted.

When numerical lower limits and numerical upper limits are listed herein, ranges from any lower limit to any upper limit are contemplated.

It should be understood that the foregoing description is only illustrative of the aspects of the disclosed embodiment. Various alternatives and modifications can be devised by those skilled in the art without departing from the aspects of the disclosed embodiment. Accordingly, the aspects of the disclosed embodiment are intended to embrace all such alternatives, modifications and variances that fall within the scope of the appended claims. Further, the mere fact that different features are recited in mutually different dependent or independent claims does not indicate that a combination of these features cannot be advantageously used, such a combination remaining within the scope of the aspects of the invention.

What is claimed is:

1. A biodegradable polylactic acid based film composition comprising: from 90 to 99 wt. % of one or more polylactic acid resins and from 1 to 10 wt. % of one or more polyterpene resin additives based on the total film structure, wherein the film composition exhibits a water vapor transmission rate of less than or equal to 35 g/100 in²/day/mil.

2. The film composition of claim 1, wherein the film exhibits a water vapor transmission rate of less than or equal to 30 g/100 in²/day/mil.

3. The film composition of claim 2, wherein the film exhibits a water vapor transmission rate of less than or equal to 25 g/100 in²/day/mil.

4. The film composition of claim 1, wherein the one or more polyterpene resin additives range from 3 to 6 wt. % based on the total film structure.

5. The film composition of claim 1, wherein the one or more polyterpene resin additives are chosen from the group consisting of a polymerized d-limonene, a polymerized beta-pinene, a polymerized synthetic approximation of d-limonene and beta-pinene, and combinations thereof.

6. The film composition of claim 5, wherein the one or more polyterpene resin additives comprises polymerized d-limonene.

7. The film composition of claim 1 having a thickness ranging from 0.5 mil to 20 mil.

8. The film composition of claim 1, wherein the one or more polylactic acid resins includes a polylactic acid blend resin comprising polylactic acid with one or more native plant starches.

9. The film composition of claim 8, wherein the one or more native plant starches are chosen from the group consisting of corn, wheat, tapioca, potato and combinations thereof.

10. The film composition of claim 1 further including one or more skin layers on one or both sides of the polylactic acid containing layer, wherein the skin layers are chosen from the group consisting of ethylene-propylene random copolymer, ethylene-propylene-butene-1 terpolymer, high density polyethylene, medium density polyethylene, low density polyethylene, linear low density polyethylene, propylene-butene-1 copolymer, ethylene vinyl alcohol copolymer, amorphous polyester, ionomer and combinations thereof.

11. The film composition of claim 10 wherein the thickness of the more or more skin layers range from 1 to 20 gauge units.

12. The film composition of claim 10 further including one or more tie layers interposed between the one or more skin layers and the polylactic acid containing layer, wherein the tie layer is a maleic anhydride modified polyethylene or polypropylene.

13. The film composition of claim 12 wherein the thickness of the more or more tie layers range from 1 to 20 gauge units.

14. The film composition of claim 1 further including one or more coating layers on one or both sides of the polylactic acid containing layer, wherein the coating layers are chosen from the group consisting of PVDC, PVOH, acrylic, LTSC and combinations thereof.

15. The film composition of claim 14 wherein the thickness of the more or more coating layers range from 0.2 to 10 gauge units. The film composition of claim 1 further including one or more vacuum deposited aluminum layers on one or both sides of the polylactic acid containing layer.

16. The film composition of claim 16 wherein the optical density of the film composition is from 0.5 to 4.0.

17. The film composition of claim 1 further including from 1 to 20 wt. % of one or more agro-derived bioresins chosen from the group consisting of green polyethylene, green polypropylene, green polyester, and combinations thereof.

18. The film composition of claim 10, wherein the one or more skin layers further include from 5 to 95 wt. % of one or more agro-derived bioresins chosen from the group consisting of green polyethylene, green polypropylene, green polyester, and combinations thereof.

19. A method of making a biodegradable polylactic acid based film composition comprising the steps of:
providing a composition including 90 to 99 wt. % of one or more polylactic acid resins and from 1 to 10 wt. % of one or more polyterpene resin additives, and
extruding the composition to form a mono-layer film,
wherein the film exhibits a water vapor transmission rate of less than or equal to 35 g/100 in²/day/mil.

20. The method of claim 20, wherein the one or more polyterpene resin additives are chosen from the group consisting of a polymerized d-limonene, a polymerized beta-pinene, a polymerized synthetic approximation of d-limonene and beta-pinene, and combinations thereof.

21. The method of claim 20, wherein the film composition has a thickness ranging from 0.5 mil to 20 mil.

22. The method of claim 20, wherein the one or more polylactic acid resins includes a polylactic acid blend resin comprising polylactic acid with one or more native plant starches.

23. The method of claim 23, wherein the one or more native plant starches are chosen from the group consisting of corn, wheat, tapioca, potato and combinations thereof.

24. The method of claim 20, further including coextruding one or more skin layers on one or both sides of the mono-layer film, wherein the skin layers are chosen from the group consisting of ethylene-propylene random copolymer, ethylene-propylene-butene-1 terpolymer, high density polyethylene, medium density polyethylene, low density polyethylene, linear low density polyethylene, propylene-butene-1 copolymer, ethylene vinyl alcohol copolymer, amorphous polyester, ionomer and combinations thereof.

25. The method of claim 25 further including coextruding one or more tie layers interposed between the one or more skin layers and the polylactic acid containing layer, wherein the tie layer is a maleic anhydride modified polyethylene or polypropylene.

26. The method of claim 20 further including coating one or more coating layers on one or both sides of the of the mono-layer film, wherein the coating layers are chosen from the group consisting of PVDC, PVOH, acrylic, LTSC and combinations thereof.

27. The method of claim 20 further including vacuum metallizing one or more aluminum layers on one or both sides of the mono-layer film, wherein the optical density of the film composition is from 0.5 to 4.0.

28. The method of claim 20 further including surface treating one or more surfaces of the mono-layer film by corona discharge treatment, flame treatment, plasma treatment, or combinations thereof.

29. The method of claim 20 further including machine direction orienting the mono-layer film.

30. The method of claim 20 further including transverse direction orienting the mono-layer film.

31. The method of claim 20 further including the combination of machine direction orienting and transverse direction orienting the mono-layer film.

32. The method of claim 20 further including from 1 to 20 wt. % of one or more agro-derived bioresins chosen from the group consisting of green polyethylene, green polypropylene, green polyester, and combinations thereof.

33. The method of claim 25, wherein the one or more skin layers further include from 5 to 95 wt. % of one or more agro-derived bioresins chosen from the group consisting of green polyethylene, green polypropylene, green polyester, and combinations thereof.

34. A method of using a biodegradable polylactic acid based film composition comprising the steps of:
providing a film composition including 90 to 99 wt. % of one or more polylactic acid resins and from 1 to 10 wt. % of one or more polyterpene resin additives, wherein the film composition exhibits a water vapor transmission rate of less than or equal to 35 g/100 in²/day/mil, and
utilizing the film composition in frozen food packaging, snack food packaging, beverage packaging, labeling applications, pet food packaging applications for achieving recyclability, compostability and biodegradability following use.
